(19) United States
(12) Patent Application Publication
(10) Pub. No.: US 2026/0150696 A1
(43) Pub. Date: May 28, 2026

(54) SEMICONDUCTOR PACKAGE

(71) Applicant: Samsung Electronics Co., Ltd., Suwon-si (KR)

(72) Inventors: Sanghyeon Jeong, Suwon-si (KR); Gyuhyeong Kim, Suwon-si (KR)

(21) Appl. No.: 19/394,380

(22) Filed: Nov. 19, 2025

(30) Foreign Application Priority Data
Nov. 25, 2024 (KR) 10-2024-0169474

(51) Int. Cl. H01L 23/552; H01L 23/00; H01L 23/29; H01L 23/31; H01L 23/36

(52) U.S. Cl. CPC H10W 42/20; H10W 40/10; H10W 74/117; H10W 74/473; H10W 72/342; H10W 90/724; H10W 90/736

(57) ABSTRACT

A semiconductor package may include a package substrate, a semiconductor chip, a molding member, a resin pattern and a metal shield layer. The package substrate may be mounted on the package substrate. The semiconductor chip may be mounted on the package substrate and the semiconductor chip may include a second surface including a flat portion and a recessed portion. The molding member may be on the package substrate to cover a lower portion of the semiconductor chip and sidewalls of the semiconductor chip. The molding member including at least filler and resin. The resin pattern may fill the recessed portion of the second surface of the semiconductor chip, and the resin pattern may include a material the same as a material of the resin included in the molding member. The metal shield layer may cover the flat portion of the semiconductor chip, the molding member, and the resin pattern.

### CROSS-REFERENCE TO RELATED APPLICATION

This application claims priority under 35 USC § 119 to Korean Patent Application No. 10-2024-0169474, filed on Nov. 25, 2024, in the Korean Intellectual Property Office (KIPO), the contents of which are incorporated by reference herein in their entirety.

### BACKGROUND

A semiconductor chip embedded in the semiconductor package may be damaged by heat generated inside the semiconductor package. Therefore, the semiconductor package may have a structure suitable for dissipating the heat generated inside the semiconductor package to outside of the semiconductor package. In addition, the semiconductor package may have a structure suitable for reducing defects caused by electromagnetic waves generated inside the semiconductor package or introduced from the outside of the semiconductor package. The semiconductor package may include a metal layer for heat dissipation.

### SUMMARY

When a semiconductor package includes a metal layer for heat dissipation, a crack may occur in a portion of the metal layer due to a difference between a tensile stress of an element contacting the metal layer and a tensile stress of the metal layer. Accordingly, a reliability of the semiconductor package may be decreased.

Some aspects of the present disclosure provide semiconductor packages having excellent heat dissipation and electrostatic shielding characteristics and high reliability.

According to some implementations of the present disclosure, there is provided a semiconductor package. The semiconductor package may include a package substrate; a semiconductor chip mounted on the package substrate, the semiconductor chip including a first surface facing the package substrate and a second surface opposing the first surface, and the second surface including a flat portion and a recessed portion; a molding member on the package substrate to cover a lower portion of the semiconductor chip and sidewalls of the semiconductor chip, the molding member exposing the second surface of the semiconductor chip, and the molding member including at least filler and resin; a resin pattern filling the recessed portion of the second surface of the semiconductor chip, and the resin pattern including a material the same as a material of the resin included in the molding member; and a metal shield layer covering the flat portion of the semiconductor chip, the molding member, and the resin pattern.

According to some implementations of the present disclosure, there is provided a semiconductor package. The semiconductor package may include a package substrate; a semiconductor chip mounted on the package substrate, the semiconductor chip including a first surface on which conductive bumps are formed and a second surface opposing the first surface, the second surface including a flat portion and a recessed portion, and the first surface facing the package substrate; a molding member on the package substrate to cover the lower portion of the semiconductor chip and sidewalls of the semiconductor chip; a filling pattern filling the recess portion of the second surface of the semiconductor, the filling pattern including at least one material among materials included in the molding member, and the filling pattern being distinct from the molding member; a metal shield layer covering the flat portion of the semiconductor chip, the molding member, and the filling pattern, the metal shield layer overlapping with an upper surface of the package substrate.

According to some implementations of the present disclosure, there is provided a semiconductor package. The semiconductor package may include a package substrate; a semiconductor chip mounted on the package substrate, the semiconductor chip including a first surface facing the package substrate and a second surface opposing the first surface, and the second surface including a flat portion and a recessed portion; a molding member filling a gap between the package substrate and the first surface of the semiconductor chip, the molding member covering sidewalls of the semiconductor chip and an upper surface of the package substrate and exposing the second surface of the semiconductor chip, and the molding member including at least a filler and a resin; a resin pattern filling the recessed portion of the second surface of the semiconductor chip, the resin pattern including a resin the same as the resin included in the molding member, and at least a portion of the resin pattern extending to an edge of the second surface of the semiconductor chip; and a metal shield layer covering the flat portion of the semiconductor chip, the molding member and the resin pattern.

Based on the foregoing package configurations and other structures and methods described herein, in some implementations, the heat generated in a semiconductor package may be transferred to a metal shield layer and easily dissipated to outside of the semiconductor package. Therefore, defects of the semiconductor package due to the heat may be decreased. In addition, in some implementations, electromagnetic waves emitted from the semiconductor package to outside or introduced into the inside of the semiconductor package may be shielded by the metal shield layer. Therefore, defects of the semiconductor package due to the electromagnetic waves may be decreased.

In some implementations, since the metal shield layer and the resin pattern have excellent adhesion property and a difference between tensile stresses of the metal shield layer and the resin pattern is not great, a crack of the metal shield layer directly on the resin pattern may not occur. In addition, since a portion of the metal shield layer contacts the resin pattern on the second surface of the semiconductor chip, a contact area between the metal shield layer and the semiconductor material on the second surface of the semiconductor chip may be decreased. Accordingly, a difference between tensile stresses of the metal shield layer and the second surface of the semiconductor chip contacting thereon may be decreased. Therefore, the crack of the metal shield layer due to the difference between the tensile stresses may be decreased.

However, the positive effects provided by the present disclosure are not limited to those described above, and others will be understood from the subsequent description.

### BRIEF DESCRIPTION OF THE DRAWINGS

FIGS. 1 and 2 are cross-sectional views illustrating examples of semiconductor packages;

FIGS. 3 to 6 are plan views illustrating examples of elements included in semiconductor packages;

FIGS. 7 to 13, 15, and 16 are cross-sectional views illustrating an example of a method of manufacturing a semiconductor package; and

FIG. 14 is a plan view illustrating the example of the method of manufacturing a semiconductor package.

### DETAILED DESCRIPTION

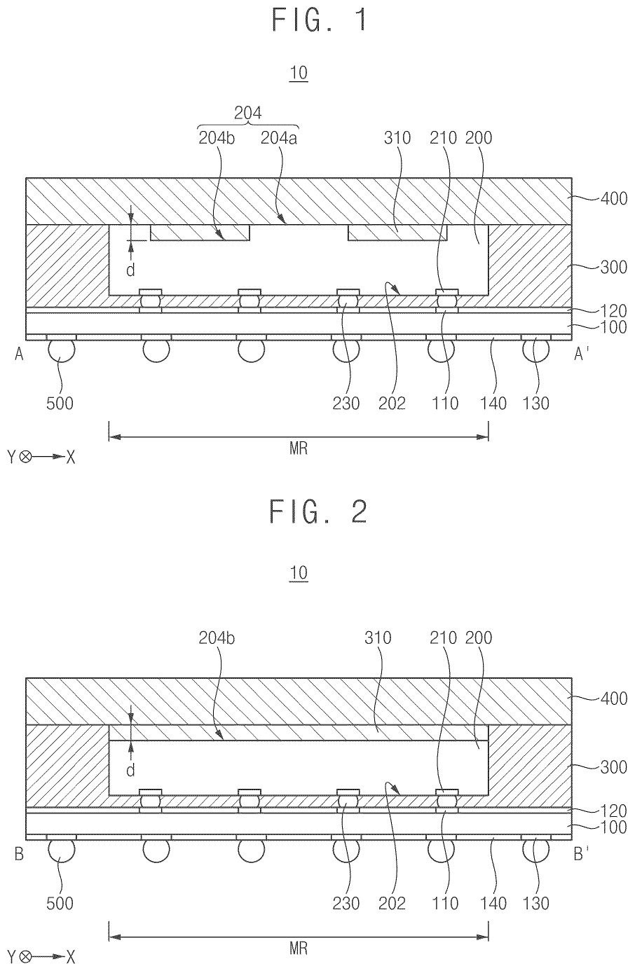

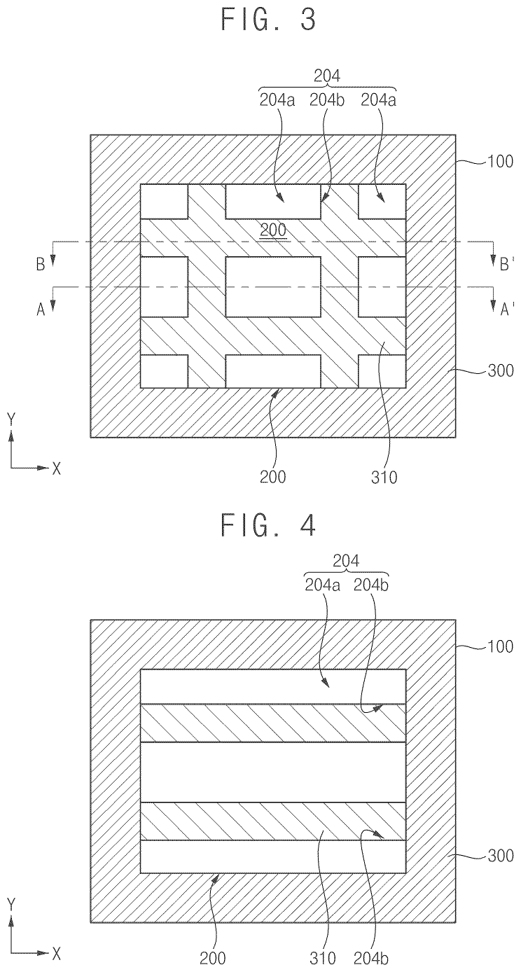

FIGS. 1 and 2 are cross-sectional views illustrating examples of semiconductor packages. FIGS. 3 to 6 are plan views illustrating a molding member, a resin pattern, and a semiconductor chip under a metal shield layer in examples of semiconductor packages.

FIG. 1 is a cross-sectional view taken along A-A′ line of FIG. 3, and FIG. 2 is a cross-sectional view taken along B-B′ line of FIG. 3.

Referring to FIGS. 1 to 3, the semiconductor package 10 may include a package substrate 100, a semiconductor chip 200, a resin pattern 310, a molding member 300 and a metal shield layer 400. The semiconductor package 10 may further include external connection members 500.

The package substrate 100 may be a substrate having an upper surface and a lower surface facing opposite one other. For example, the package substrate 100 may be a printed circuit board (PCB). The printed circuit board may be a multilayer circuit board having vias and various circuits therein.

The package substrate 100 may include insulation layers and wirings inside the insulation layers. The package substrate 100 may further include a plurality of upper substrate pads 110 and a plurality of lower substrate pads 130. The wirings may include internal wirings as channels for electrically connecting the semiconductor chips having different types.

The upper substrate pads 110 may be exposed at an upper surface of the package substrate 100. An upper insulation layer 120 may be disposed between the upper substrate pads 110, and at least a portion of the upper substrate pads 110 may be exposed by the upper insulation layer 120. The lower substrate pads 130 may be exposed at the lower surface of the package substrate 100. The lower insulation layer 140 may be disposed between the lower substrate pads 130, and at least a portion of each of the lower substrate pads 130 may be exposed by the lower insulation layer 140.

In some implementations, a chip mounting region MR may be disposed at a center of the upper surface of the package substrate 100. The upper substrate pads 110 may be arranged in the chip mounting region MR of the package substrate 100. The upper substrate pads 110 may be arranged in an array form in the chip mounting region MR. In a plan view, the package substrate 100 may have a square shape.

The lower substrate pads 130 may be provided to input and output electrical signals. The external connection members 500 may be disposed on a lower surface of the lower substrate pads 130 for electrical connection to an external device. For example, the external connection member 500 may be a solder ball. The semiconductor package 10 may be mounted on a module substrate using the solder balls to form a memory module.

The semiconductor chip 200 may be mounted on the upper surface of the package substrate 100. The semiconductor chip 200 may be mounted on a chip mounting area MR of the package substrate 100 using, e.g., conductive bumps 230.

The semiconductor chip 200 may include a substrate including a semiconductor material. The semiconductor chip 200 may include a first surface 202 on which circuit patterns and chip pads 210 are formed, and a second surface 204 opposing the first surface 202. The first surface 202 of the semiconductor chip 200 may be disposed to face the package substrate 100.

The semiconductor material of the substrate may be exposed at the second surface 204 of the semiconductor chip 200. For example, silicon may be exposed at the second surface 204 of the semiconductor chip 200. The circuit patterns and the chip pads may not be formed on the second surface 204 of the semiconductor chip 200.

The second surface 204 of the semiconductor chip 200 may include a flat portion 204a (sometimes referred to as an upper portion), e.g., having a flat surface, and a recessed portion 204b recessed downward (e.g., in a direction toward the package substrate 100) from the flat portion 204a. The recessed portion 204b defines recesses in the second surface 204.

The semiconductor chip 200 may have a square shape, in a plan view. At least a portion of the recessed portion 204b may extend to an edge (e.g., a lateral edge) of the second surface 204 of the semiconductor chip 200. At least a portion of the recessed portion 204b may extend to at least one sidewall of the semiconductor chip 200 having the square shape.

In some implementations, as shown in FIG. 3, in a plan view, the recessed portion 204b may have a lattice shape extending in each of a first direction X (e.g., parallel to the first surface 202) and a second direction Y perpendicular to the first direction X (e.g., and parallel to the first surface 202). In the plan view, the recessed portion 204b may have a shape that is connected to each other, e.g., may form a continuous region in a plan view.

In some implementations, as shown in FIG. 4, in a plan view, a plurality of recessed portions 204b may be spaced apart in the second direction Y, and the plurality of recessed portions 204b may extend in the first direction X. In a plan view, each recessed portion 204b may have a line shape extending in the first direction X

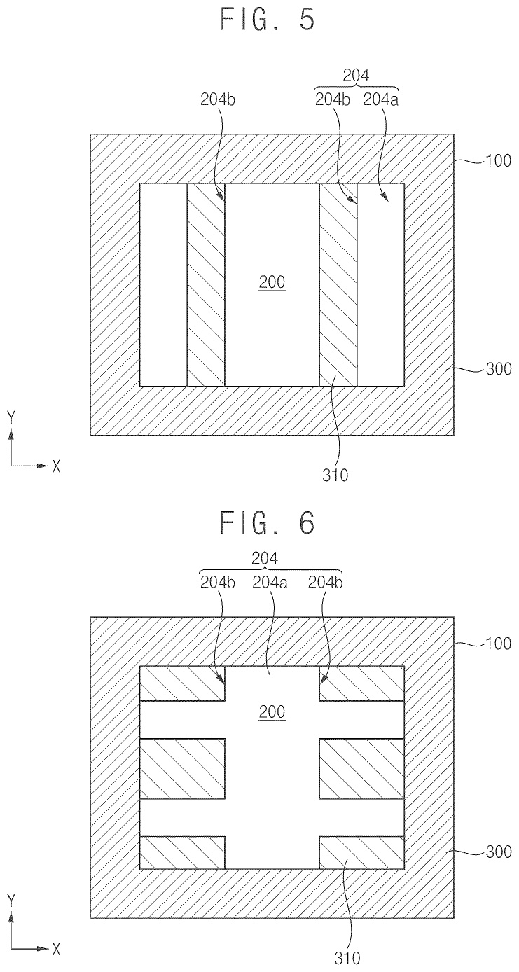

In some implementations, as shown in FIG. 5, in a plan view, a plurality of recessed portions 204b may be spaced apart in the first direction X, and the plurality of recessed portions 204b extend in the second direction Y. In a plan view, each recessed portion 204b may have a line shape extending in the first direction Y.

In some implementations, as shown in FIG. 6, in a plan view, a plurality of the recessed portions 204b may be regularly arranged (e.g., in an array), and each of the recessed portions 204b may have an isolated shape, e.g., may be discontinuous from the other recessed portions 204b.

However, an arrangement of the recessed portions 204b may be variously modified, and need not be limited to the specific examples shown in FIGS. 3 to 6.

In some implementations, the semiconductor chip 200 may be mounted on the package substrate 100 by a flip chip bonding process. The chip pads 210 of the semiconductor chip 200 may be electrically connected to the upper substrate pads 110 of the package substrate 100, respectively, using conductive bumps 230. A gap between the semiconductor chip 200 and the package substrate 100 may be formed by the conductive bumps 230.

For example, the conductive bumps 230 may include micro bumps. Each of the conductive bumps 230 may include a conductive pillar serving as a lower bump and a solder serving as an upper bump. The conductive pillar may include a copper (Cu) pillar. The solder may include, e.g., tin (Sn), Sn/Ag, Sn/Cu, Sn/In, Sn/Ag/Cu, etc.

The conductive bumps 230 under the semiconductor chip 200 may be electrically connected to the external connection member 500 via the upper substrate pad 110, the wirings in the package substrate 100, and the lower substrate pad 130. Therefore, the semiconductor chip 200 may be electrically connected to an external device by the conductive bumps 230.

The molding member 300 may be disposed on the package substrate 100 to cover the sidewalls and a bottom of the semiconductor chip 200. The molding member 300 may fill a gap between the package substrate 100 and the first surface 202 of the semiconductor chip 200, and the molding member 300 may cover the upper surface of the package substrate 100 and the sidewalls of the semiconductor chip 200. Meanwhile, the molding member 300 may not cover an upper surface of the semiconductor chip 200. Therefore, the upper surface of the semiconductor chip 200 (e.g., second surface 204) may be exposed by the molding member 300.

The molding member 300 may include an epoxy mold compound (EMC). The EMC may include a filler, a resin, and an additive. The resin may include, e.g., epoxy, a liquid crystal polymer (LCP), a polyimide (PI), a polycabonate (PC), and/or a polyethylene terephthalate (PET), etc.

In some implementations, the molding member 300 may be formed on the package substrate 100 by a molded underfill (MUF) process using a molding apparatus.

The molding member 300 may include a first molding portion 304 (labeled in FIG. 12) covering sidewalls of the semiconductor chip 200 on the package substrate 100 and a second molding portion 306 (labeled in FIG. 12) filling the gap between the package substrate 100 and the first surface 202 of the semiconductor chip 200. Meanwhile, in some implementations, the molding member 300 may not be disposed on the second surface 204 of the semiconductor chip 200.

A resin pattern 310 formed by a resin component, which is among molding materials included in the molding member 300, may be disposed in the recessed portion 204b of the second surface 204 of the semiconductor chip 200. For example, the resin pattern 310 may include a same resin as a resin included in the molding member 300. In some implementations, the resin pattern 310 may include the resin, which is one component included in the molding member 300, and may not include other components included in the molding member 300, such as fillers. Therefore, the resin pattern 310 may be a different material from the molding member 300. The resin pattern 310 and the molding member 300 may be distinct from each other. In some implementations, the resin pattern 310 includes, or is composed of, a resin that is not included in the molding member 300.

The resin pattern 310 may fill the recesses defined by recessed portion 204b. Therefore, the recessed portion 204b and the resin pattern 310 may have the same shape (e.g., in a plan view). Since the resin pattern 310 serves as a layer for filling the recessed portion 204b, the resin pattern 310 is also referred to as a filling pattern.

At least a portion of the resin pattern 310 may extend to an edge of the semiconductor chip 200. A portion of the resin pattern 310 positioned at the edge of the semiconductor chip 200 may contact the molding member 300.

In some implementations, as shown in FIG. 3, in a plan view, the resin pattern 310 may have a lattice shape extending in each of the first direction X and the second direction Y. In the plan view, the resin patterns 310 may have a shape that is connected to each other, e.g., that is continuous.

In some implementations, as shown in FIG. 4, in a plan view, a plurality of resin patterns 310 may be spaced apart in the second direction Y. Each of the resin patterns 310 may have a line shape extending in the first direction X.

In some implementations, as shown in FIG. 5, in a plan view, a plurality of resin patterns 310 may be spaced apart in the first direction X. Each of the resin patterns 310 may have a line shape extending in the second direction Y.

In some implementations, as shown in FIG. 6, in a plan view, a plurality of resin patterns 310 may be regularly arranged to be spaced apart from each other, e.g., in an array pattern. Each of the plurality of resin patterns 310 may have isolated shape, e.g., be discontinuous from other resin patterns 310.

In some implementations, a vertical depth d of the recess defined by the recessed portion 204b (or a vertical depth d of the recessed portion 204b compared to the flat portion 204a) may be less than a size (or diameter) of the filler included in the molding materials of the molding member 300. When the vertical depth d of the recess is greater than the size of the filler, the filler and the resin included in the molding material may flow together into the recessed portion 204b. In this case, the resin pattern including only resin may not be formed in the recessed portion.

In some implementations, the vertical thickness of the resin pattern 310 may be in a range of about 10 μm to about 40 μm. In order to form the resin pattern 310 thinner than 10μm, the recessed portion 204b may be formed thinner than 10 μm. When the recessed portion 204b is thinner than 10 μm, the resin component included in the molding material may not sufficiently flow into the recessed portion 204b during forming process of the molding member 300. Therefore, the resin pattern 310 having the target thickness may not be formed. The resin pattern 310 may not have a higher thermal conductivity than a semiconductor material (e.g., silicon) of the semiconductor chip. Therefore, when the resin pattern 310 is thicker than 40 μm, a thermal conductivity of the semiconductor package may decrease due to the thickness of the resin pattern 310. Accordingly, a heat dissipation effect may decrease at a contact portion between the resin pattern 310 and the metal shield layer 400.

The vertical depth d of the recessed portion 204b may be substantially the same as a vertical thickness of the resin pattern 310. Accordingly, the vertical depth d of the recessed portion 204b may be in a range of 10 μm to 40 μm.

In some implementations, an upper surface of the resin pattern 310, a flat portion 204a of the second surface 204 of the semiconductor chip 200, and an upper surface of the molding member 300 may be coplanar with each other. The upper surface of the resin pattern 310 may not protrude upward from the flat portion 204a of the second surface 204 of the semiconductor chip 200. The upper surface of the resin pattern 310, the flat portion 204a of the second surface 204 of the semiconductor chip, and the upper surface of the molding member 300 may be substantially flat.

The metal shield layer 400 may extend over the upper surface of the molding member 300, the resin pattern 310 on the semiconductor chip 200, and the flat portion 204a of the second surface 204 of the semiconductor chip 200. The metal shield layer 400 may be disposed on the upper surface of the molding member 300, the resin pattern 310 on the semiconductor chip 200, and the flat portion 204a of the second surface 204 of the semiconductor chip 200. The metal shield layer 400 may contact the upper surface of the molding member 300, the resin pattern 310 on the semiconductor chip 200, and the flat portion 204a of the second surface 204 of the semiconductor chip 200. For example, at least a portion of a lower surface of the metal shield layer 400 may contact the resin pattern 310 on the semiconductor chip 200 without contacting the molding member 300 and the second surface 204 of the semiconductor chip 200. The metal shield layer 400 may be disposed to overlap with the upper surface of the package substrate 100 along a vertical direction perpendicular to the first direction X and the second direction Y.

The metal shield layer 400 may be disposed at an uppermost portion of the semiconductor package 10. In some implementations, only the metal shield layer 400 may be exposed at the uppermost portion of the semiconductor package 10.

The metal shield layer 400 may serve as a heat sink layer for effectively dissipating of the heat generated in the semiconductor chip 200. Since at least a portion of the lower surface of the metal shield layer 400 directly contacts the second surface 204 of the semiconductor chip 200, an effect of dissipating of the heat generated in the semiconductor chip 200 to an outside of the semiconductor package 10 may be enhanced.

The metal shield layer 400 may include a metal having high thermal conductivity. Since the metal shield layer 400 includes the metal, the metal shield layer 400 may serve as a layer of shielding of electromagnetic waves generated in the semiconductor chip 200 and the electromagnetic waves introduced from the outside of the semiconductor package 10. In some implementations, the metal shield layer 400 may include copper (Cu), stainless steel, aluminum (Al), tin (Sn), nickel (Ni), gold (Au), platinum (Pt), titanium (Ti), or an alloy thereof, etc. In some implementations, the metal shield layer 400 may have a structure in which a plurality of metal layers are stacked. For example, the metal shield layer 400 may have a structure in which a stainless-steel layer, a copper layer, and a stainless-steel layer are sequentially stacked.

The metal shield layer 400 may have excellent adhesion properties with the molding member 300, and a difference between a tensile stress of the molding member 300 and a tensile stress of the metal shield layer 400 may not be great. Therefore, cracks of the metal shield layer 400 may hardly occur at a contact portion between the metal shield layer 400 and the molding member 300.

In general, the metal shield layer may not have excellent adhesion properties with the semiconductor material of the second surface of the semiconductor chip, and a difference between a tensile stress of the semiconductor material and the tensile stress of the metal shield layer may be great. Therefore, cracks due to the difference between the tensile stresses may frequently occur at a contact portion between the metal shield layer and the semiconductor material of the second surface of the semiconductor chip.

However, in some implementations described herein, the second surface 204 of the semiconductor chip 200 may include a recessed portion 204b, and the resin pattern 310 composed of the resin provided from the molding material of the molding member 300 may be formed inside the recessed portion 204b. At least a portion of the metal shield layer 400 may contact the resin pattern 310. Since the metal shield layer 400 has excellent adhesion properties with the resin pattern 310, cracks of the metal shield layer 400 may hardly occur at the contact portion between the resin pattern 310 and the metal shield layer 400.

In the semiconductor package 10, since the resin pattern 310 contacting the metal shield layer 400 is included, a horizontal area of the contact portion between the metal shield layer 400 and the semiconductor material of the semiconductor chip 200 may be decreased. Therefore, the crack of the metal shield layer 400 due to differences between tensile stresses of the metal shield layer 400 and the semiconductor material of the semiconductor chip 200 may be decreased. In addition, adhesion properties between the metal shield layer 400 and the each of the molding member 300, the resin pattern 310, and the flat portion 204a of the second surface 204 of the semiconductor chip 200 may be improved.

As described above, the semiconductor package 10 may include the metal shield layer 400, so that the heat generated in the semiconductor chip 200 may be effectively dissipated, and the electromagnetic waves in the semiconductor package 10 may be shielded. In addition, as the metal shield layer 400 contacts the molding member 300, the resin pattern 310, and the flat portion 204a of the second surface 204 of the semiconductor chip 200, cracks of the metal shield layer 400 and a delamination of the metal shield layer 400 may be decreased.

Hereinafter, an example of a method for manufacturing the semiconductor package illustrated in FIGS. 1 to 3 is described. It will be understood that similar methods, following the same principles, can be used for manufacturing the semiconductor packages of FIGS. 4 to 6, and other semiconductor packages described herein.

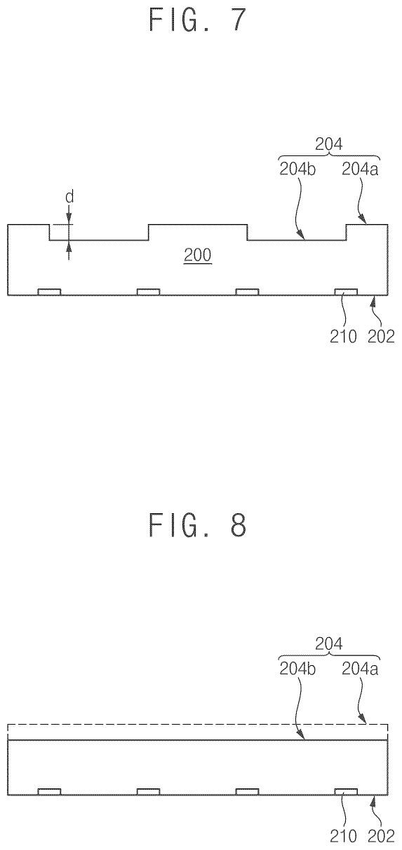

FIGS. 7 to 16 are cross-sectional views and plan views illustrating an example of a method of manufacturing a semiconductor package.

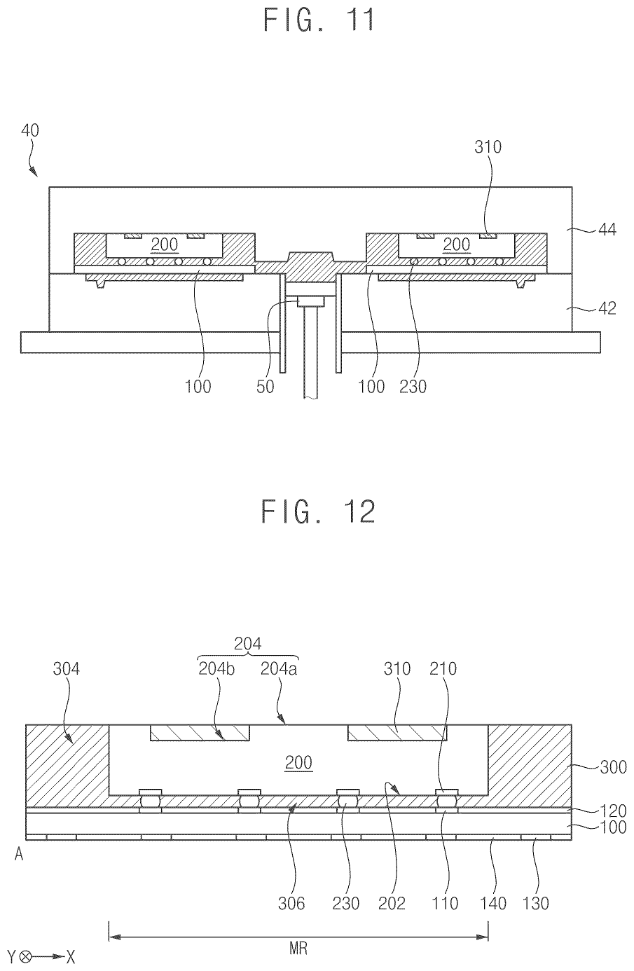

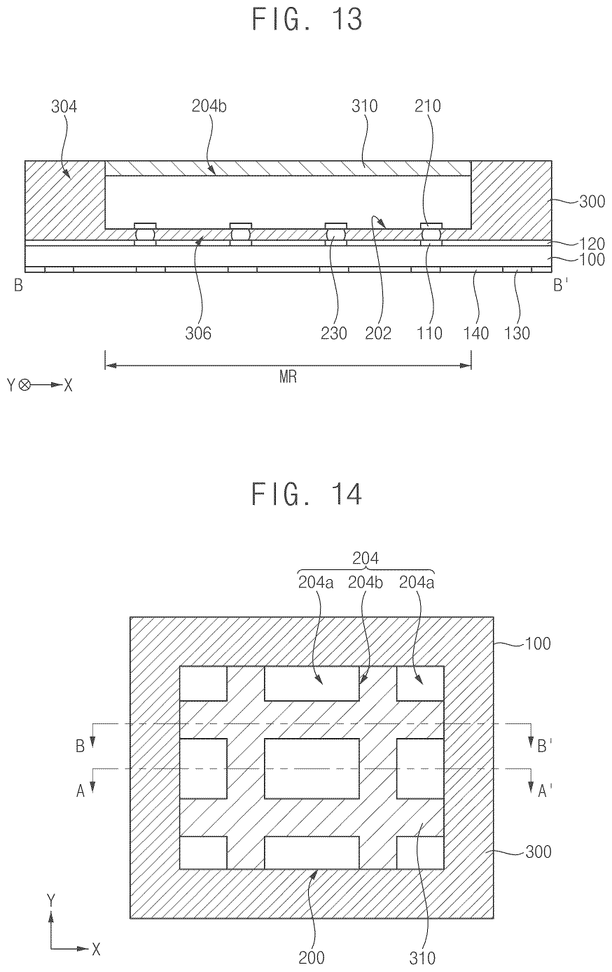

FIGS. 7 to 9, 12, 13, 15, and 16 are cross-sectional views associated with manufacture of the semiconductor package; FIGS. 10 and 11 are cross-sectional views associated with forming a molding member and a resin pattern on a package substrate by a molding apparatus; and FIG. 14 is a plan view.

FIGS. 7, 12, and 15 are cross-sectional views taken along section A-A′ of FIG. 3, and FIGS. 8, 13, and 16 are cross-sectional views taken along section B-B′ of FIG. 3. FIGS. 7, 12, and 15 show a flat portion and a recessed portion of a second surface of the semiconductor chip together, and FIGS. 8, 13, and 16 show only the recessed portion of the second surface of the semiconductor chip.

Referring to FIGS. 7 and 8, a semiconductor chip 200 having a first surface 202 on which circuit patterns and chip pads 210 may be formed and a second surface 204 opposing the first surface may be provided.

A portion of the second surface 204 of the semiconductor chip 200 may be removed to form a recessed portion 204b. Accordingly, the second surface 204 of the semiconductor chip 200 may include a flat portion 204a and recessed portions 204b. The process for forming the recessed portions 204b may include, e.g., a laser cutting process. In FIG. 8, a portion indicated by a dotted line indicates a vertical position of the flat portion 204a of the second surface 204 of the semiconductor chip 200.

The semiconductor chip 200 may have a rectangular shape, when viewed in a plan view. At least one portion of the recessed portion 204b may extend to an edge of the semiconductor chip 200. At least one portion of the recessed portion 204b may extend to at least one side of the semiconductor chip 200 having the rectangular shape.

In some implementations, as shown in FIG. 3, in a plan view, the recessed portion 204b may have a lattice shape extending in each of the first direction X and the second direction Y perpendicular to the first direction X.

In some implementations, as shown in FIG. 4, in a plan view, a plurality of the recessed portions 204b may extend in the first direction X, and may be spaced apart in the second direction Y.

In some implementations, as shown in FIG. 5, in a plan view, a plurality of recessed portions 204b may extend in the second direction Y, and may be spaced apart in the first direction X.

In some implementations, as shown in FIG. 6, in a plan view, a plurality of recessed portions 204b may be regularly arranged to be spaced apart from each other, e.g., in an array configuration. Each of the plurality of recessed portions 204b may have an isolated shape. As noted above, other configurations of the recessed portion(s) 204b are also within the scope of this disclosure.

A vertical depth d of the recessed portion 204b may be less than a size (or a diameter) of filler included in the molding material of the molding member 300. In some implementations, the vertical depth d of the recessed portion 204b is in a range of 10 μm to 40 μm.

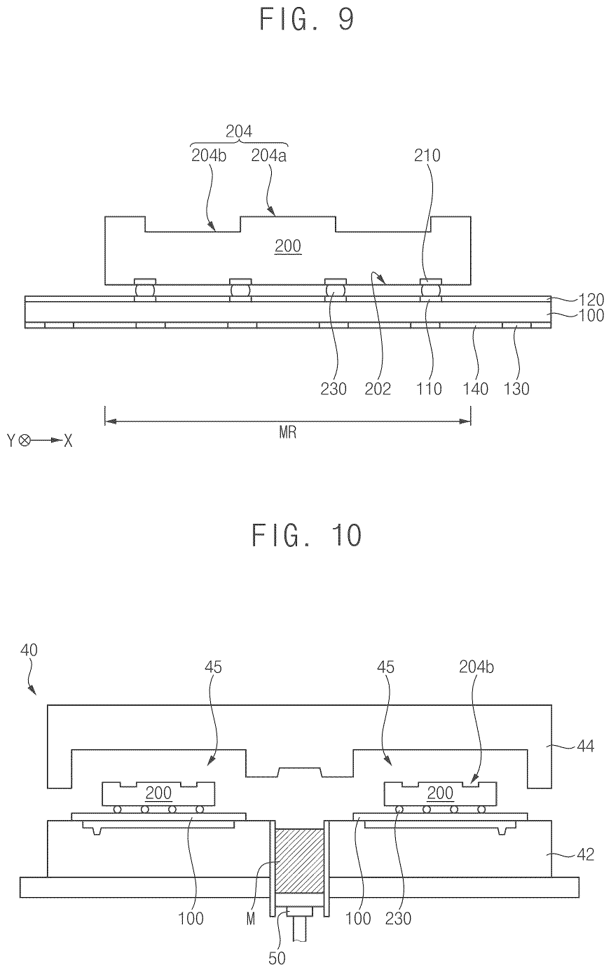

Referring to FIG. 9, the semiconductor chip 200 may be mounted on the package substrate 100 by interposing conductive bumps 230.

In some implementations, after preparing a strip substrate including a plurality of package substrates 100, individualized semiconductor chips 200 may be placed on the strip substrate. The package substrate 100 may be a multilayer circuit board having an upper surface and a lower surface facing opposite one other. For example, the package substrate 100 may be a printed circuit board (PCB) including wirings in each of multi-layers and vias for connecting the wirings.

Although only one semiconductor chip 200 is illustrated in the drawing, the number is not limited thereto. For example, a plurality of semiconductor chips 200 may be mounted on one strip substrate. The strip substrate may be cut along a cutting line by a subsequent sawing process, so that individual semiconductor packages may be formed.

The semiconductor chip 200 may be mounted on a chip mounting area MR of a package substrate 100 by performing a flip chip bonding process.

For example, conductive bumps 230 may be formed on chip pads 210 of a first surface 202 of the semiconductor chip 200, flux may be applied on surfaces of the conductive bumps 230, and the semiconductor chip 200 may be placed on the package substrate 100. The conductive bumps 230 may be interposed between the upper surface of the package substrate 100 and the first surface 202 of the semiconductor chip 200. The conductive bumps 230 may be disposed on the upper substrate pads 110 of the package substrate 100. Next, the conductive bumps 230 may be boned on the upper substrate pad 110 by a reflow process.

For example, the conductive bumps 230 may be formed by a plating process. Alternatively, the conductive bumps 230 may be formed by a screen printing process, a deposition process, or the like. For example, each of the conductive bumps 230 may include a conductive pillar serving as a lower bump and a solder serving as an upper bump. The conductive pillar may include, e.g., a copper pillar. The solder may include, e.g., Sn, Sn/Ag, Sn/Cu, Sn/In, t Sn/Ag/Cu, or the like.

Referring to FIGS. 10 to 14, a molding member 300 may be formed on a package substrate 100 to cover a semiconductor chip 200.

The molding member 300 may be formed by performing a molded underfill (MUF) process using a molding apparatus 40. The molding apparatus 40 may include a mold having a lower mold 42 and an upper mold 44, and the lower mold 42 and the upper mold 44 may be clamped to each other to form a molding space 45 for sealing of semiconductor chip 200. The molding apparatus 40 may be a transfer molding apparatus that flows a liquid molding material M into the molding space 45 to partially seal the semiconductor chip 200.

The semiconductor chip 200 may be placed in the molding space 45. While the lower mold 42 and the upper mold 44 are clamped, the molding material M may be flowed into the molding space at high temperature and high pressure. Therefore, liquid molding material M may be introduced inside the molding space and then solidifies to form a molding member 300 covering a portion of the surface of the semiconductor chip 200. For example, the molding member 300 may include an epoxy mold compound (EMC). The epoxy mold compound may include a filler, a resin, and an additive. The resin may include, e.g., epoxy, LCP (liquid crystal polymer), PI (polyimide), PC (polycarbonate), and/or PET (polyethylene terephthalate).

A tablet-like molding material M from a molding material supply unit may be supplied onto a plunger 50, and the molding material M may be heated to have fluidity. Then, as the plunger 50 rises, liquid molding material M may flow into the molding space by a pressuring of the plunger 50.

The mold may include a vent section for exhausting gas within the molding space 45.

The molding member 300 may cover a sidewall and a lower portion of the semiconductor chip 200 on the package substrate 100. The molding member 300 may include a first molding portion 304 covering the side walls of the semiconductor chip 200 on the package substrate 100 and a second molding portion 306 filling the gap between the package substrate 100 and the first surface of the semiconductor chip 200. The second surface 204 of the semiconductor chip 200 may not be covered by the molding member 300. That is, the molding member 300 may not be disposed on the second surface 204 of the semiconductor chip 200.

When the processes for forming the molding member 300 are performed, a portion of the edge of the molding space 45 and the recessed portion 204b may be in communication with each other. Therefore, in the processes for forming the molding member 300, the resin components included in the molding material M may flow into the recessed portion 204b of the second surface 204 of the semiconductor chip 200, and thus the resin pattern 310 may be formed inside the recessed portion 204b. Since the size or diameter of the filler included in the molding material M is greater than the depth of the recessed portion 204b, the filler may hardly, or not at all, flow into the recessed portion 204b. The resin pattern 310 may include material the same as material of the resin included in the molding member 300. Since the resin pattern 310 is formed inside the recessed portion 204b, the resin pattern 310 may have a shape the same as a shape of the recessed portion 204b.

In some implementations, the upper surface of the resin pattern 310, the flat portion 204a of the second surface 204 of the semiconductor chip 200 and the upper surface of the molding member 300 may be coplanar with each other. The upper surface of the resin pattern 310 may not protrude from the flat portion 204a of the second surface 204 of the semiconductor chip 200.

In some implementations, after forming the molding member 300 and the resin pattern 310, the upper surface of the resin pattern 310, the flat portion 204a of the second surface 204 of the semiconductor chip 200 and the upper surface of the molding member 300 may be planarized by a planarization process, such as a grinding process.

In some implementations, depending on the arrangement and the shape of the recessed portion 204b, the resin pattern 310 may be formed to have one of the arrangements and the shapes illustrated in FIGS. 4 to 6.

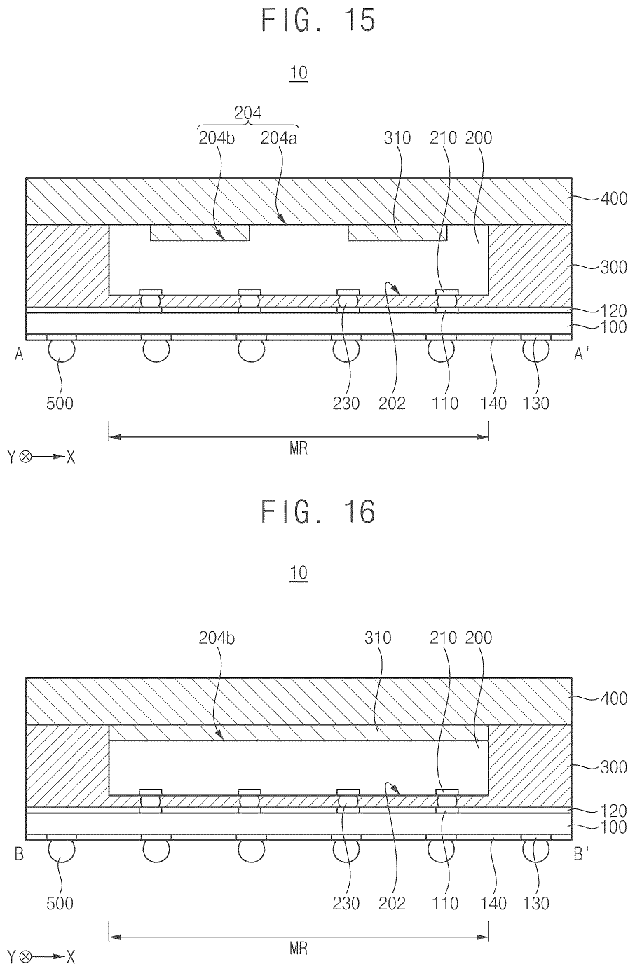

Referring to FIGS. 15 and 16, a metal shield layer 400 may be formed to contact the molding member 300, the resin pattern 310 on the semiconductor chip 200, and the flat portion 204a of the second surface 204 of the semiconductor chip 200.

The metal shield layer 400 may be arranged on an uppermost portion of the semiconductor package 10, and an upper portion of the semiconductor package 10 may be covered by the metal shield layer 400. Therefore, in some implementations, only the metal shield layer 400 may be exposed at the uppermost portion of the semiconductor package 10.

In some implementations, the metal shield layer 400 may include Cu, stainless steel, Al, Sn, Ni, Au, Pt, or an alloy thereof. In some implementations, the metal shield layer 400 may have a structure in which a plurality of metal layers are stacked. For example, the metal shield layer 400 may have a structure in which a stainless steel layer, a copper layer, and a stainless steel layer are sequentially stacked.

Thereafter, external connection members 500, such as solder balls, may be formed on the lower substrate pads 130 on the lower surface of the package substrate 100. Accordingly, the semiconductor package 10 of FIG. 1 may be manufactured.

The semiconductor package may include a semiconductor device, such as a logic device or a memory device. The semiconductor package may include, e.g., logic devices such as a central processing unit CPU, MPU, an application processor AP, volatile memory devices such as an SRAM device, a DRAM device, or the like, and nonvolatile memory devices such as a flash memory device, a PRAM device, an MRAM device, an RRAM device, or the like.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The foregoing is illustrative of various examples. Although these examples have been described, those skilled in the art will readily appreciate that many modifications are possible without materially departing from the scope of the present disclosure.

What is claimed is:

1. A semiconductor package, comprising:
a package substrate;
a semiconductor chip mounted on the package substrate, the semiconductor chip including a first surface facing the package substrate and a second surface opposing the first surface, wherein the second surface includes an upper portion and a recessed portion;
a molding member on the package substrate, wherein the molding member covers the first surface of the semiconductor chip and sidewalls of the semiconductor chip, wherein the molding member exposes the second surface of the semiconductor chip, and wherein the molding member comprises a filler and a resin material;
a resin pattern filling a recess defined by the recessed portion of the second surface of the semiconductor chip, wherein the resin pattern includes the resin material included in the molding member; and
a metal shield layer extending over the upper portion of the second surface, the molding member, and the resin pattern.

2. The semiconductor package of claim 1, wherein a vertical depth of the recess is in range of 10 μm to 40 μm.

3. The semiconductor package of claim 1, wherein a vertical depth of the recess is smaller than a size of the filler included in the molding member.

4. The semiconductor package of claim 1, wherein the upper portion of the second surface, an upper surface of the molding member, and an upper surface of the resin pattern are coplanar with each other.

5. The semiconductor package of claim 1, wherein the recessed portion extends to a lateral edge of the semiconductor chip.

6. The semiconductor package of claim 1, wherein, in a plan view, the recessed portion has:
a lattice shape,
a line shape extending in a first direction parallel to the first surface of the semiconductor chip, or
a line shape extending in a second direction perpendicular to the first direction.

7. The semiconductor package of claim 1, wherein the recessed portion comprises a plurality of recessed sections that are regularly arranged and discontinuous from one another in a plan view.

8. The semiconductor package of claim 1, wherein the metal shield layer is in contact with the upper portion of the second surface, the molding member, and the resin pattern.

9. The semiconductor package of claim 1, wherein the metal shield layer is spaced apart from an upper surface of the package substrate, and wherein the metal shield layer overlaps the upper surface of the package substrate along a vertical direction perpendicular to the first direction.

10. A semiconductor package, comprising:
a package substrate;
a semiconductor chip mounted on the package substrate, the semiconductor chip including a first surface on which conductive bumps are arranged and a second surface opposing the first surface, wherein the second surface includes an upper portion and a recessed portion, and wherein the first surface faces the package substrate;
a molding member on the package substrate, wherein the molding member covers the first surface of the semiconductor chip and sidewalls of the semiconductor chip;
a filling pattern filling a recess defined by the recessed portion of the second surface of the semiconductor chip, the filling pattern including at least one material that is included in materials included in the molding member, wherein the filling pattern is distinct from the molding member; and
a metal shield layer extending over the upper portion of the second surface, the molding member, and the filling pattern, wherein the metal shield layer overlaps with an upper surface of the package substrate along a vertical direction.

11. The semiconductor package of claim 10, wherein the molding member includes a filler and a resin, and wherein the filling pattern includes the resin.

12. The semiconductor package of claim 10, wherein a vertical depth of the recess is in a range of 10 μm to 40 μm.

13. The semiconductor package of claim 10, wherein the recessed portion extends to a lateral edge of the semiconductor chip.

14. The semiconductor package of claim 10, wherein the upper portion of the second surface, an upper surface of the molding member, and an upper surface of the filling pattern are coplanar with each other.

15. The semiconductor package of claim 10, wherein the molding member fills a gap between the package substrate and the first surface of the semiconductor chip.

16. The semiconductor package of claim 10, wherein the molding member includes an epoxy mold compound (EMC).

17. A semiconductor package, comprising:
a package substrate;
a semiconductor chip mounted on the package substrate, the semiconductor chip including a first surface facing the package substrate and a second surface opposing the first surface, and wherein the second surface includes an upper portion and a recessed portion;
a molding member filling a gap between the package substrate and the first surface of the semiconductor chip, wherein the molding member covers sidewalls of the semiconductor chip and an upper surface of the package substrate and exposes the second surface of the semiconductor chip, and wherein the molding member includes a filler and a resin;
a resin pattern filling a recess defined by the recessed portion of the second surface of the semiconductor chip, the resin pattern including a resin that is included in the molding member, wherein the resin pattern extends to a lateral edge of the second surface of the semiconductor chip; and
a metal shield layer extending over the upper portion of the second surface, the molding member, and the resin pattern.

18. The semiconductor package of claim 17, wherein a vertical depth of the recess is in a range of 10 μm to 40 μm.

19. The semiconductor package of claim 17, wherein the upper portion of the second surface, an upper surface of the molding member, and an upper surface of the resin pattern are coplanar with each other.

20. The semiconductor package of claim 17, wherein the molding member includes an epoxy mold compound (EMC).
